(19) United States
(12) Patent Application Publication
(10) Pub. No.: US 2006/0071821 A1
(43) Pub. Date: Apr. 6, 2006

(54) Method for verifying a circuit function

(76) Inventor: Masaharu Kimura, Kawasaki (JP)

Correspondence Address: ARENT FOX PLLC, 1050 CONNECTICUT AVENUE, N.W., SUITE 400, WASHINGTON, DC, 20036, US

(21) Appl. No.: 11/048,846

(22) Filed: Feb. 3, 2005

(30) Foreign Application Priority Data
Sep. 22, 2004 (JP) 2004-274478

(51) Int. Cl. H03M 7/00

(52) U.S. Cl. 341/50

(57) ABSTRACT

A circuit function verification method that simulates an operating state caused by an analog signal. When differential input DP and differential input DM are inputted to a differential interface circuit, a signal change detection section monitors the state of the differential input DP and the differential input DM and detects a change in the logical level of the differential input DP and the differential input DM. For example, the signal change detection section detects that the differential input DP and the differential input DM are at the same logical level or that the differential input DP and the differential input DM changed simultaneously to logical levels opposite to each other. A signal conversion section generates an inverted signal according to the change in the logical level of the differential input DP and the differential input DM detected by the signal change detection section by inverting an output value before the change in the logical level of the differential input DP and the differential input DM for the required time. By doing so, an inverted signal pulse appears on differential output and an analog transient response is simulated.

### CROSS-REFERENCE TO RELATED APPLICATIONS

This application is based upon and claims the benefits of priority from the prior Japanese Patent Application No. 2004-274478, filed on Sep. 22, 2004, the entire contents of which are incorporated herein by reference.

### BACKGROUND OF THE INVENTION

(1) Field of the Invention

This invention relates to a circuit function verification method and, more particularly, to a circuit function verification method for simulating the operation of a differential interface circuit which generates a differential circuit output signal (differential output) according to the differential between differential input signals (differential input) and for verifying the function of a circuit including the differential interface circuit.

(2) Description of the Related Art

Conventionally, it has been hoped that simulation techniques used for verifying the functions of large scale integrated circuits (LSIs), more particularly, of circuits in which analog circuits and digital circuits mingle will be improved.

A differential interface circuit to which analog differential input is inputted and from which digital differential output is outputted is an example of circuits in which analog circuits and digital circuits mingle. FIG. 12 is a circuit diagram showing an example of a differential interface circuit. A differential interface circuit includes a differential amplifier Al, single-ended circuits A2 and A3, and an AND circuit G1. The differential amplifier A1 detects the difference in voltage between differential input DP and differential input DM and outputs it as a data signal D. Basically, the single-ended circuits A2 and A3 are also differential circuits. Each of them compares the voltage of a signal inputted to its signal input terminal to the ground with a certain voltage value and outputs a comparison result. That is to say, the single-ended circuit A2 compares the voltage of the differential input DP with a certain voltage value and outputs a comparison result. The single-ended circuit A3 compares the voltage of the differential input DM with a certain voltage value and outputs a comparison result. The AND circuit G1 calculates the logical product of signals obtained by inverting the signals outputted from the single-ended circuits A2 and A3 and outputs a result as an EOP signal.

When a logical simulation is done to verify the design of an LSI including such an interface circuit, an interface circuit model simplified so as to apply to the logical simulation is used. This shortens processing time. FIG. 13 is a circuit diagram showing an example of a conventional interface circuit model for logical simulations. A differential analog signal cannot be handled by digital logic, so it is converted to a digital value (high/low level) and is inputted to the interface circuit model. In this example, the differential amplifier A1 is replaced with buffers B1 and B2 for inverting and outputting an input signal. A digital signal (DP′), being differential input inputted to a non-inverting input, is outputted as differential output D′. Similarly, the single-ended circuits A2 and A3 are replaced with buffers B3 and B4, respectively. The buffer B3 inverts and outputs the digital signal (DP′) inputted to the non-inverting input. The buffer B4 inverts and outputs a digital signal (DM′) inputted to an inverting input. An AND circuit G2 calculates the logical product of signals outputted from the buffers B3 and B4 and outputs a result as an EOP′ signal. In conventional design verification, the differential output D′ and the differential output EOP′ generated by the above-mentioned interface circuit model have been used for verifying a logical circuit.

The digital signal (DM′) inputted to the inverting input may be used as differential input. In this case, the differential amplifier A1 should be replaced with a buffer for inverting and outputting the digital signal (DM′) inputted to the inverting input and the differential output D′ is outputted.

Moreover, a simulation apparatus for doing a circuit simulation with an analog signal, deciding at the time of a certain voltage value being exceeded that a signal in a digital circuit has changed, and doing a digital logical simulation in which an adjustment is made so that the signal change transmitted from the circuit simulation to the logical simulation will occur at the exact time is proposed (see, for example, Japanese Unexamined Patent Publication No. Hei10-340280, paragraph nos. [0020]-[0031] and FIG. 1).

The above-mentioned differential interface circuit is applied to the processing of differential input (analog signal) used as an interface signal for high-speed data transfer realized by IEEE1394, Universal Serial Bus (USB), or Ethernet (registered trademark). FIG. 14 shows the relationship between differential input to and differential output from the differential interface circuit. FIG. 14 shows changes with time in the voltage values of the differential input DP and the differential input DM and the differential output D.

Usually one of the differential input DP and the differential input DM to the differential interface circuit is at the high level (H) and the other is at the low level (L). Hereinafter, a state in which the logical levels of two input signals are different from each other will be referred to as a differential state. Intervals a and e in FIG. 14 show a differential state. However, to indicate a special state in a data transfer control procedure, a special input state in which both of the differential input DP and the differential input DM are at L or H is used in data transfer. Hereinafter, a state in which the logical level of two input signals are the same will be referred to as a same-logical-level state. Intervals b, c, and din FIG. 14 show a same-logical-level state. When the differential interface circuit is really applied, the differential input DP and the differential input DM are connected to an external personal computer used as a host, a repeater located between a host and the differential interface circuit, or a cable. Accordingly, changes in signals inputted to the differential interface circuit are not in synchronization with the operation of the differential interface circuit and the waveform of the signals deforms by the influence of cables. In addition, there are minute variations in the waveform of these input signals. For example, there are jitters and variations in pulse width. In a differential state in which the difference in voltage between the differential input DP and the differential input DM is great, the differential output D is not influenced by a minute change in the waveform of input signals. A differential amplifier amplifies the difference in voltage between differential input signals and outputs signal voltage. In a same-logical-level state, the difference in voltage between differential input signals may be reversed due to, for example, a comparatively small undershoot in the waveform of the input signals, resulting in inverted differential output. For example, in the interval b in FIG. 14, the differential output D is inverted due to an undershoot in the waveform of the differential input DM. In the interval c where the waveform of the differential input DM recovers from the undershoot, the differential output D is inverted again. In the interval d, the differential output D is inverted again due to an oscillation which occurs when the differential input DP changes to H. Essentially, such differential output must be ignored as data in a logical circuit. Similarly, when the logical levels of two differential input signals change to polarities opposite to each other, minute variations in one or both of them may cause a change in differential output.

Similarly, if an intersection lowers when the logical levels of two differential input signals change simultaneously to polarities opposite to each other, single-ended circuit output (EOP) transiently changes to H. FIG. 15 shows the relationship between differential input and differential output at the time of the intersection of the waveforms of differential signals lowering. In this example, the waveform of the differential input DP deforms and the intersection of the differential input DP and the differential input DM lowers. This causes a transient change in the single-ended circuit output EOP.

With conventional interface circuit models, however, a signal obtained by replacing an analog signal by a digital value is used as an input signal, so a change in differential output caused by a minute change specific to an analog signal cannot be simulated. Accordingly, functions at the time of the occurrence of such a change in waveform cannot be verified. Even if there is a problem with design, it cannot be detected. As a result, in some LSIs the following case has arisen. An internal circuit detects such a change in waveform, recognizes wrong that there is a change in signal, and malfunctions.

In addition, with the above-mentioned technique for doing a circuit simulation with an analog signal and doing a digital logical simulation at a certain voltage value, it is difficult to efficiently generate a new signal in response to a change in differential input signal if a specific condition exists, such as if differential input signals are at the same logical level.

As stated above, with circuit function verification methods using the conventional differential interface circuit models, it is difficult to verify functions by simulating the operation of actual circuits caused by analog signals.

### SUMMARY OF THE INVENTION

The present invention was made under the background circumstances described above. An object of the present invention is to provide a circuit function verification method using a differential interface circuit model in which simulations are done so that operation caused by an analog signal can be handled in the function verification of a logical circuit.

To attain the object, there is provided a circuit function verification method for simulating the operation of a differential interface circuit which generates a differential circuit output signal according to the differential between differential input signals and for verifying the function of a circuit including the differential interface circuit. This circuit function verification method comprises the steps of inputting a first differential input signal and a second differential input signal, being a pair of differential signals, and detecting a change in the logical level of the first differential input signal and/or the second differential input signal by a signal change detection section; and generating an inverted signal by inverting a differential circuit output value before the change in the logical level of the first differential input signal and/or the second differential input signal for a required period of time according to the detected change in the logical level of the first differential input signal by a signal conversion section and the second differential input signal and treating the inverted signal as a differential interface circuit output signal by the signal conversion section.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a schematic view of the present invention applied to an embodiment.

FIG. 2 is a timing chart snowing the relationship between differential input to and differential output from a differential interface circuit model.

FIG. 3 shows the case where a differential interface circuit model is modeled by an I/O cell.

FIG. 4 shows the case where the differential interface circuit model is modeled by a test bench.

FIG. 5 shows the structure of the differential interface circuit model according to an embodiment of the present invention.

FIG. 6 is an example of the format of a data packet inputted to the differential interface circuit model.

FIG. 7 is a timing chart showing the operation of the differential interface circuit model.

FIG. 8 shows the relationship between an internal clock and differential output.

FIG. 9 shows the structure of an example of a time control circuit for producing a time delay.

FIG. 10 is a flow chart showing a differential output generation process according to the embodiment of the present invention.

FIG. 11 shows relationships among components in circuit function verification to which the differential interface circuit model according to the embodiment of the present invention is applied.

FIG. 12 is a circuit diagram showing an example of a differential interface circuit.

FIG. 13 is a circuit diagram showing an example of a conventional interface circuit model for a logical simulation.

FIG. 14 shows the relationship between differential input to and differential output from a differential interface circuit.

FIG. 15 shows the relationship between differential input and differential output at the time of the intersection of the waveforms of differential signals lowering.

### DESCRIPTION OF THE PREFERRED EMBODIMENTS

Embodiments of the present invention will now be described with reference to the drawings. An overview of the present invention applied to the embodiment will be given first and then the concrete contents of the embodiment will be described.

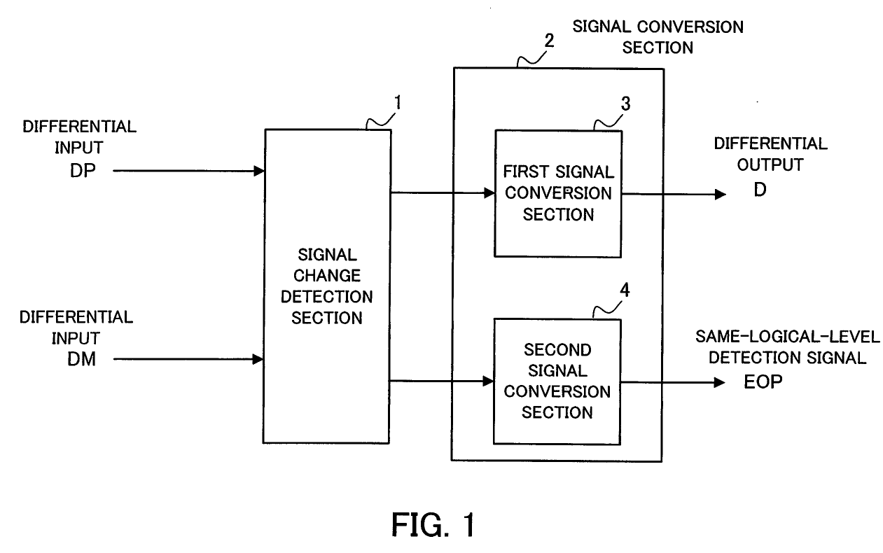

FIG. 1 is a schematic view of the present invention applied to the embodiment.

A differential interface circuit model comprises a signal change detection section 1 into which differential input DP and differential input DM, being binary data (H or L) corresponding to analog signals, are inputted and a signal conversion section 2 for accepting output signals corresponding to a change in the logical level of the differential input DP and the differential input DM detected by the signal change detection section 1 and for converting them into differential output D and a same-logical-level detection signal EOP indicative of whether the logical level of the differential input DP and the logical level of the differential input DM are the same. The signal conversion section 2 includes a first signal conversion section 3 for outputting the differential output D and a second signal conversion section 4 for outputting the same-logical-level detection signal EOP.

Usually the differential input DP and the differential input DM are inputted in a differential state, in which the logical level of one input is H and the logical level of the other input is L, and indicate predetermined data values. For example, DP>DM and DP<DM indicate H and L, respectively. When a specific state is indicated, such as when transferred data ends in a transfer, the differential input DP and the differential input DM are inputted in a same-logical-level state in which their logical level are both H or L. In this example, the differential input DP and the differential input DM are inputted as digital signals having the value of H or L.

The signal change detection section 1 detects a predetermined change (from H to L or from L to H) in the logical level of the differential input DP and the differential input DM and informs the signal conversion section 2 of the occurrence of the predetermined change in the logical level of the differential input DP and the differential input DM. In this example, when the signal change detection section 1 detects that the logical levels of the differential input DP and the differential input DM changed to the same level (H or L), the signal change detection section 1 informs the first signal conversion section 3 of it. Moreover, when the signal change detection section 1 detects that the logical levels of the differential input DP and the differential input DM changed simultaneously to polarities opposite to each other (that the logical level of one input has changed from H to L and the logical level of the other input has changed from L to H), the signal change detection section 1 informs the second signal conversion section 4 of it. By the way, a change in differential output caused by a minute variation in differential input, being an analog signal, is simulated by an inverted signal.

When the signal change detection section 1 detects that the logical levels of the differential input DP and the differential input DM charged to the same level, the first signal conversion section 3 outputs an inverted signal obtained by inverting the value of the differential output D which it is outputting at that time as the differential output D for the time required. The inverted signal can be varied from the time when that the differential input DP and the differential input DM changed are at the same logical level is detected to the time when their logical levels change or while the inverted signal is being outputted. If a plurality of inverted signals are outputted, they can be varied by a time parameter set in advance until the next change in the logical level of the differential input DP and the differential input DM. By doing so, a change in the differential output D caused by, for example, an undershoot in the waveform of differential input at the time of the differential input DP and the differential input DM being in a same-logical-level state can be simulated.

When the signal change detection section 1 detects that the logical levels of the differential input DP and the differential input DM changed simultaneously to polarities opposite to each other, the second signal conversion section 4 generates the same-logical-level detection signal EOP with the frequency required. By doing so, a change in the differential output D caused by, for example, the lowering of an intersection due to the deformation of the waveform of differential input at the time of the logical levels of the differential input DP and the differential input DM simultaneously changing to polarities opposite to each other can be simulated.

In the above-mentioned differential interface circuit model, when the signal change detection section 1 detects that the logical levels of the differential input DP and the differential input DM changed to the same level, the first signal conversion section 3 outputs an inverted signal obtained by inverting the differential output D which it is outputting at that time. In addition, the signal change detection section 1 detects that the logical levels of the differential input DP and the differential input DM changed simultaneously to polarities opposite to each other, the second signal conversion section 4 outputs the same-logical-level detection signal EOP for the required duration.

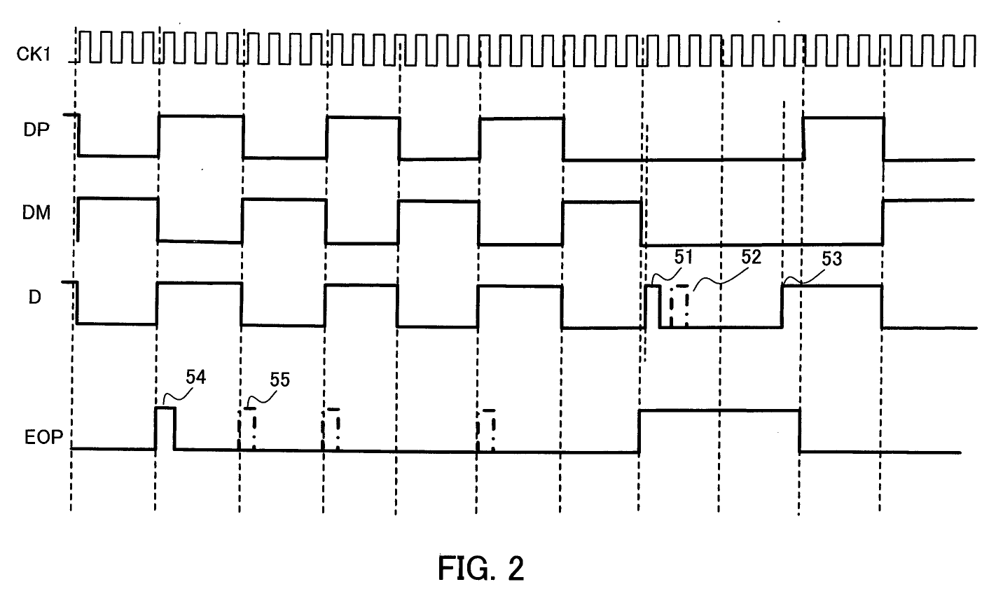

FIG. 2 is a timing chart showing the relationship between differential input to and differential output from the differential interface circuit model. In FIG. 2, CK1 indicates an internal clock.

In this differential interface circuit model, an inverted signal 51 is outputted as the differential output D in an interval where the logical level of the differential input DP and the differential input DM are the same. The width or edges of the inverted signal 51 depends on a time parameter. Another inverted signal 52 can be outputted after the inverted signal 51 as occasion demands. In addition, differential output 53 outputted at the time of the change from a same-logical-level state to a differential state can be outputted before the same-logical-level detection signal EOP by the method described later. As stated above, an analog transient response which occurs due to a change of an analog signal can be simulated in a same-logical-level state, at the time of a change to a same-logical-level state, and at the time of the change from a same-logical-level state to a differential state.

When the logical levels of the differential input DP and the differential input DM change simultaneously to polarities opposite to each other, an EOP signal 54 with narrow pulse width (corresponding to one clock) is generated. An EOP signal 55 can be generated with the frequency required as occasion demands. Any EOP signals can be generated according to a change in the differential input DP or the differential input DM in this way.

The embodiment of the present invention will now be described in detail by referring to the drawings with the case where the differential interface circuit model is applied to a data packet receiving circuit as an example.

An actual differential interface circuit is contained in an LSI chip to be designed as a differential I/O cell. Accordingly, the above-mentioned differential interface circuit model for simulating the operation of a differential interface circuit is included in a chip model or an external test bench to do logical simulations for verifying the design of the LSI.

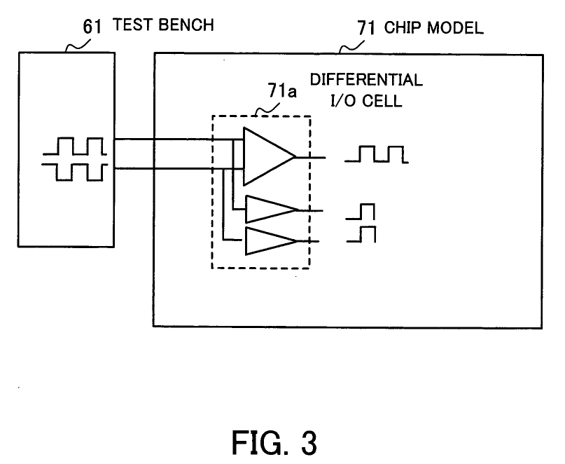

The case where the above-mentioned differential interface circuit model is included in a chip model will now be described. FIG. 3 shows the case where the differential interface circuit model is modeled by an I/O cell. If the differential interface circuit model is implemented in a chip model, a differential I/O cell 71a obtained by modeling the differential interface circuit model by an I/O cell is included in a chip model 71. In this case, input signals (differential input) generated by a test bench 61 are inputted to the chip model 71 to perform a test. The input signals generated by the test bench 61 are converted by the differential I/O cell 71a and are used for doing logical simulations.

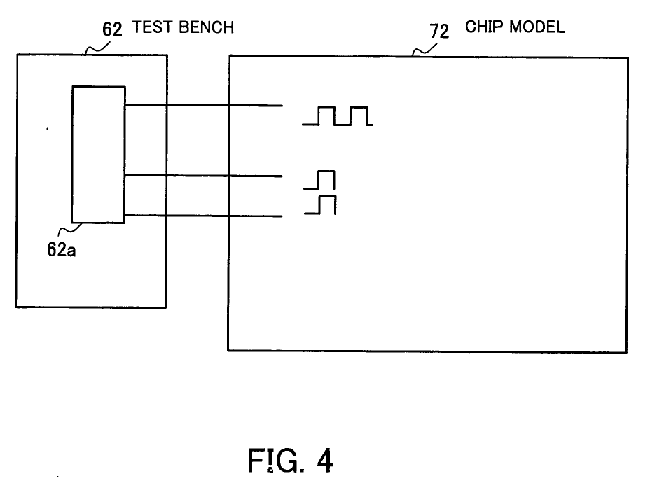

Next, the case where the above-mentioned differential interface circuit model is included in an external test bench will be described. FIG. 4 shows the case where the differential interface circuit model is modeled by a test bench. If the differential interface circuit model is implemented in an external test bench, a test signal generation circuit 62a for generating differential output on the basis of the differential interface circuit model is included in a test bench 62. In this case, the differential output generated by the test signal generation circuit 62a included in the test bench 62 is outputted to a chip model 72 and logical simulations are done.

In both cases, if binary test data (H or L) are given as the differential input DP and the differential input DM, differential output suitable for logical simulations is generated.

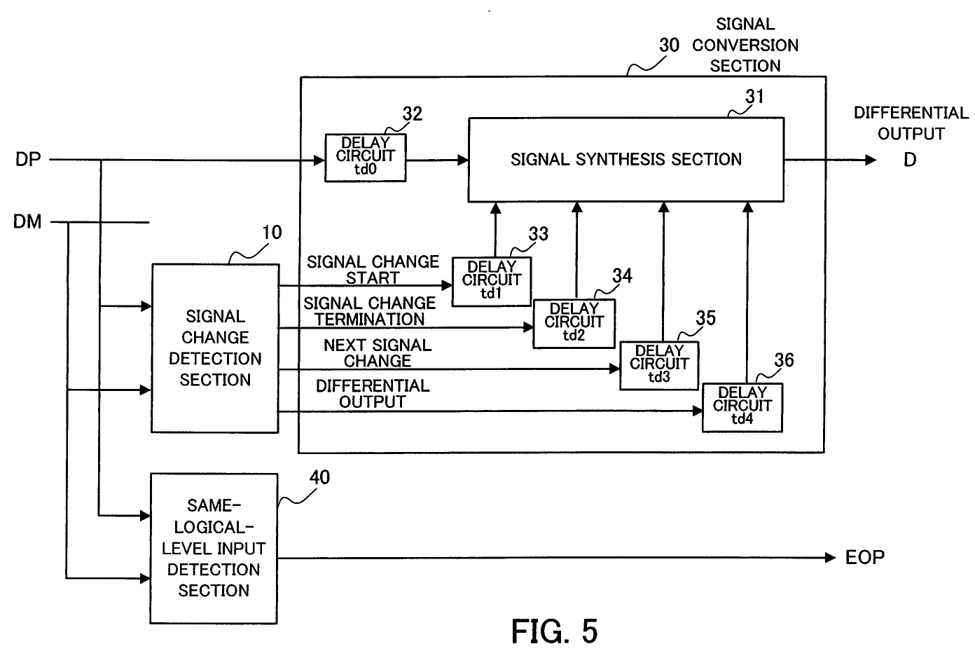

The differential interface circuit model according to the embodiment of the present invention will now be described. FIG. 5 shows the structure of the differential interface circuit model according to the embodiment of the present invention. For example, this differential interface circuit model is included in a chip model as an I/O cell.

The differential interface circuit model comprises a signal change detection section 10 into which differential input DP and differential input DM are inputted, a signal conversion section 30 into which the differential input DP and a signal outputted from the signal change detection section 10 are inputted and which generates differential output D, and a same-logical-level input detection section into which the differential input DP and the differential input DM are inputted and which outputs a same-logical-level detection signal.

When the signal change detection section 10 detects that the logical levels of the differential input DP and the differential input DM changed to the same level, the signal change detection section 10 outputs various timing signals for generating an inverted signal which are superimposed on the differential output D to delay circuits 32, 33, 34, 35, and 36 included in the signal conversion section 30. To be concrete, when the signal change detection section 10 detects that the logical levels of the differential input DP and the differential input DM changed to the same level, the signal change detection section 10 generates a timing signal by which a change is made in the differential output D by the inverted signal (signal change start), a timing signal by which the outputting of the inverted signal is terminated and the differential output D is restored to its original state (signal change termination), a timing signal by which a change is made in the differential output D by the next inverted signal (next signal change), and a timing signal by which the outputting of the differential output D is started after the termination of the same-logical-level state (differential output) and sends them to the signal conversion section 30.

The signal conversion section 30 receives the signals outputted from the signal change detection section 10 and outputs the differential output D. The signal conversion section 30 includes the delay circuit td0 (32), the delay circuit td1 (33), the delay circuit td2 (34), the delay circuit td3 (35), and the delay circuit td4 (36) each of which delays an input signal in accordance with a time parameter set in advance and a signal synthesis section 31 which synthesizes and outputs signals outputted from the delay circuits 32, 33, 34, 35, and 36. The signal synthesis section 31 accepts the signals outputted from the delay circuits 32, 33, 34, 35, and 36 and generates and outputs the differential output D. The delay circuit td0 (32) accepts the differential input DP, delays it by one clock cycle, and outputs it to the signal synthesis section 31. The delay circuit td1 (33) accepts the signal change start timing signal outputted from the signal change detection section 10, delays it by time td1 set in advance, and outputs it to the signal synthesis section 31. The delay circuit td2 (34) accepts the signal change termination timing signal outputted from the signal change detection section 10, delays it by time td2 set in advance, and outputs it to the signal synthesis section 31. The delay circuit td3 (351 accepts the next signal change timing signal outputted from the signal change detection section 10, delays it by time td3 set in advance, and outputs it to the signal synthesis section 31. That is to say, delay time td0 is actually added to the signals delayed and outputted by the delay circuit td1 (33), the delay circuit td2 (34), and the delay circuit td3 (35).

The delay circuit td4 (36) accepts the differential output timing signal outputted from the signal change detection section 10, delays it by time (td0-td4) by using the delay time td4 set in advance, and outputs it to the signal synthesis section 31. As a result, the differential output D after the termination of the same-logical-level state is outputted before a timing signal (EOP=L) by which the same-logical-level state is terminated is generated. td0, td1, td2, td3, and td4 are time parameters set in advance. These time parameters may be set to random values in an arbitrary cycle. When the signal change detection section 10 detects that the logical levels of the differential input DP and the differential input DM changed to the same level, each delay circuit sends a signal to the signal synthesis section 31 after the elapse of designated time. The signal synthesis section 31 receives the signal outputted from each delay circuit and generates predetermined data output changes as the differential output D for a predetermined period of time. By doing so, a change in differential input, being an analog signal, which occurs in a same-logical-level state and which is often missed can be generated as the differential output D.

A same-logical-level input detection section 40 generates a same-logical-level detection signal (EOP) in a same-logical-level state (H)/differential state (L) with the frequency required according to a change in the logical level of the differential input DP and the differential input DM. If data packets are transferred, EOP indicates the end of a packet. For example, when the logical levels of the differential input DP and the differential input DM change simultaneously to polarities opposite to each other, a single-ended circuit may generate an EOP signal due to the deformation of the waveform of differential input. When the same-logical-level input detection section 40 detects a predetermined change in the logical level of the differential input DP and the differential input DM, the same-logical-level input detection section 40 simulates the detection of a same-logical-level state caused by such deformation of the waveform of differential input by generating the EOP signal at predetermined intervals. In intervals where the logical level of the differential input DP and the differential input DM are the same, the EOP signal remains at H.

The operation of the differential interface circuit model having the above-mentioned structure will now be described. A data packet, being a signal inputted to the differential interface circuit model, will be described first and then the operation of the differential interface circuit model will be described with a timing chart.

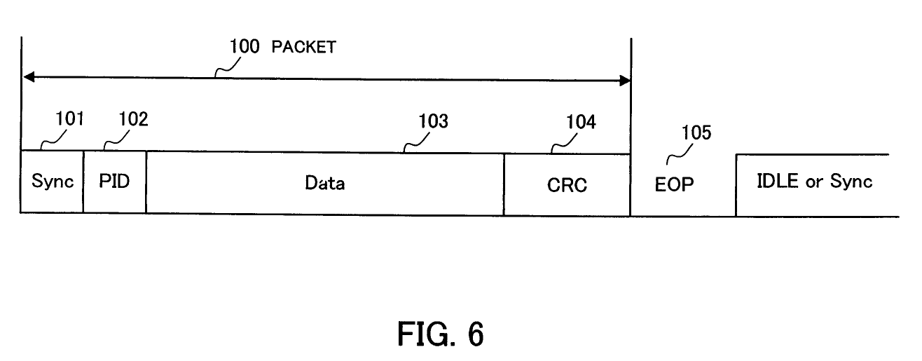

FIG. 6 is an example of the format of a data packet inputted to the differential interface circuit model. A data packet 100 includes, for example, a sync bit section 101 the length of which is one byte, a PID bit section 102 the length of which is one byte, a data section 103 the length of which is the required number of bytes and which is data to be transferred, and a CRC bit section 104 the length of which is two bytes. The data packet 100 and a subsequent EOP bit section 105 the length of which is two bytes and which separates the data packet 100 are inputted to the differential interface circuit model as differential input in a cycle determined by a predetermined data transfer rate. The EOP bit section 105 is followed by a sync bit section in the next data packet or an idle state (IDLE).

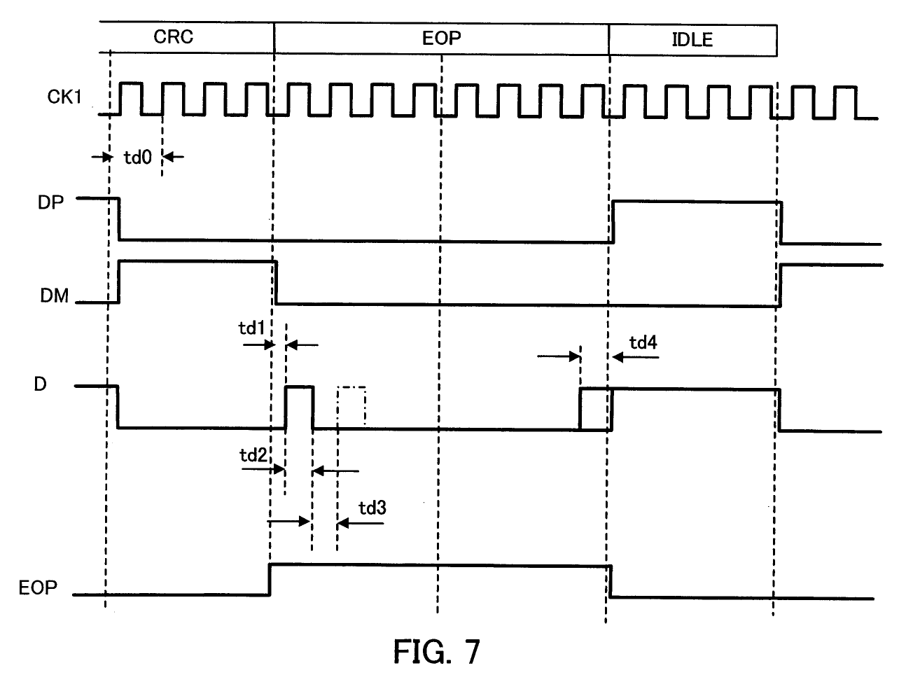

FIG. 7 is a timing chart showing the operation of the differential interface circuit model. In this example, changes in the differential output D in intervals where CRC, EOP, and IDLE are outputted as the differential input DP and the differential input DM are shown. In the CRC interval, the differential input DP and the differential input DM are in a differential state and the binary data of the differential input DP is different from that of the differential input DM. That is to say, if the binary data of the differential input DP is, for example, H, then the binary data of the differential input DM is L. In the EOP interval indicative of the end of a data packet, the differential input DP and the differential input DM are in a same-logical-level state and the binary data of the differential input DP is the same as that of the differential input DM. That is to say, if the binary data of the differential input DP is, for example, H, then the binary data of the differential input DM is also H. In the IDLE interval, the same-logical-level state is released and the binary data of the differential input DP is different from that of the differential input DM.

In the differential interface circuit model, when that the binary data of the differential input DP is the same as that of the differential input DM is detected after the start of the EOP interval, an inverted signal pulse obtained by inverting the value of the differential output D which is being outputted at that time is outputted after the elapse of time set by the time parameter td1. In this example, a pulse signal by which the logical level of the differential output D becomes H in a short interval is generated. The width of this pulse signal is determined by the time parameter td2. At this time the logical level of the EOP signal also changes to H. As a result, a state in which the short inverted signal pulse appears in the differential output D is simulated by the leading edge of the EOP signal.

While the same-logical-level state continues, the next inverted signal is outputted after the elapse of time set by the time parameter td3 as occasion demands. In the EOP interval, the EOP signal remains at H. As a result, when the EOP signal is at H, a state in which the short inverted signal pulse appears in the differential output D is simulated.

When the start of the IDLE interval is detected, the differential output D is changed to an IDLE state (H, in this example) by a clock. This clock precedes a clock by which the EOP signal is changed to L. The interval between these two clocks is determined by the time parameter td4. As a result, a state in which the differential output D goes into IDLE is simulated by the EOP signal at the H level. Variations will occur in a cycle determined by a data transfer rate. Therefore, in this example a delay of td0 is given when the logical levels of the differential input DP and the differential input DM are not the same. As a result, when that the differential input changes from the same-logical-level state to an IDLE state (DP=H and DM=L) is detected, a delay of (td0-td4) is generated by the delay circuit and the differential output D in the IDLE state is generated before the detection of the IDLE state (EOP signal=L).

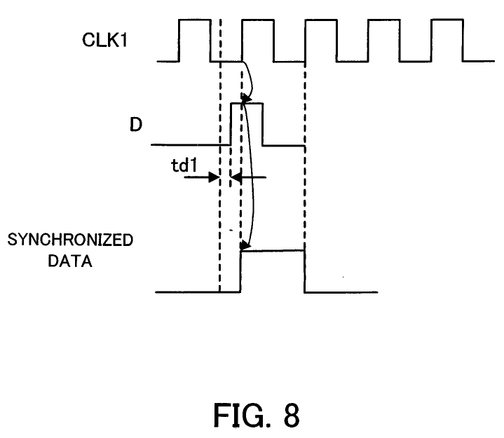

After the differential output D is outputted from the differential interface circuit, it synchronizes with an internal clock in an LSI. FIG. 8 shows the relationship between the internal clock and the differential output. For example, if a data transfer rate is 12 Mbps, then sampling is performed at an internal clock rate (60 MHz, for example) several times the data transfer rate. Accordingly, a delay of td1 may be measured by, for example, a timer or may be set to a value close to an edge the waveform of an internal clock signal at a frequency of, for example, 60 MHz. As shown in FIG. 8, if local variations in timing before sampling can be accommodated, the operation of data D being imported into an internal circuit in the LSI can be realized.

As stated above, in the differential interface circuit model according to the embodiment of the present invention, differential input, being binary data (H or L), is inputted and a pseudo analog transient response is generated as differential output. First, when the differential input is in a same-logical-level state, the start of the same-logical-level state is detected and differential output data which was being outputted before the differential input went into the same-logical-level state is inverted for a short period of time. Secondly, the termination of the same-logical-level state is detected and the differential output is changed to IDLE just before the termination of the same-logical-level state. Thirdly, a same-logical-level detection signal (EOP) is outputted with a proper frequency. By verifying the functions of circuits in an LSI by using the above-mentioned differential interface circuit model, the function of the LSI can be verified even if a change in differential output caused by an analog signal occurs. This enables thorough LSI verification. In particular, design troubles caused by an analog signal can be detected. Conventionally, it has been difficult to detect such a trouble at the design stage. In addition, signals inputted to the differential interface circuit model are digital signals, so this model is suitable for a logical simulation.

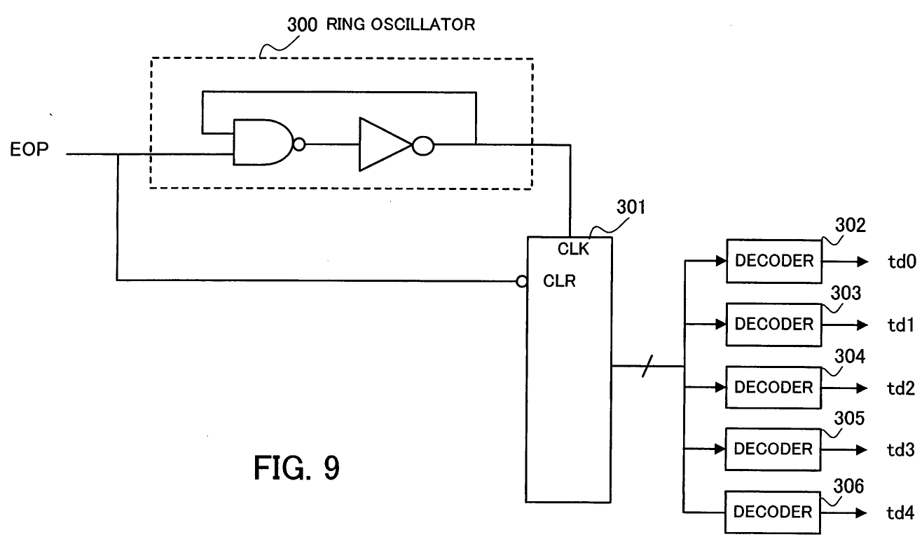

If the above operation can be realized, delay circuits of any type may be used. A time control circuit for producing a time delay with a field programmable gate array (FPGA) or the like will now be described as an example. FIG. 9 shows the structure of an example of a time control circuit for producing a time delay.

A time control circuit includes a counter 301 which accepts output from a ring oscillation circuit (ring oscillator) 300 and decoders 302, 303, 304, 305, and 306 which accept signal outputted from the counter 301. The ring oscillator 300 is started by a same-logical-level detection signal (EOP), generates a count clock signal (CLK), and outputs it to the counter 301. The counter 301 is started by the EOP, counts the number of count clock signals (CLK) outputted from the ring oscillator 300, outputs a clock count to each of the decoders 302, 303, 304, 305, and 306. When the decoder 302 detects clock count output corresponding to a predetermined delay of td0, it generates delay time control output. Similarly, when the decoders 303, 304, 305, and 306 detect clock count output corresponding to delays of td1, td2, td3, and td4, respectively, they generate delay time control output. The delay time control output is outputted to the signal synthesis section 31. In this case, delay time set by each decoder may be a fixed value, but it may be set freely within a predetermined range. In addition, by using the EOP for starting the ring oscillator 300 and the counter 301, necessary differential output can be generated not during the entire packet period but only while the EOP is being inputted.

Delay time may be generated in a clock cycle significantly shorter than a data cycle. In modeling, a ring oscillator is used and the number of clock cycles in the ring oscillator may be counted for generating delay time.

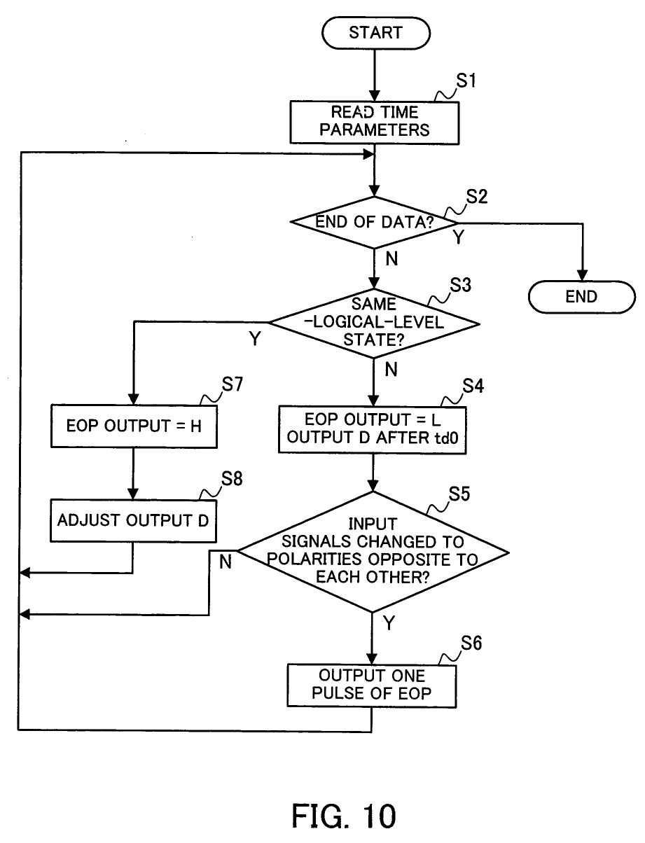

In the above descriptions, the differential interface circuit model is realized by hardware. However, the differential interface circuit model can be realized by software, such as a hardware description language or a general-purpose language. FIG. 10 is a flow chart showing a differential output generation process according to the embodiment of the present invention. Binary data (H or L) is inputted as differential input.

[Step S1] Time parameters set in advance are read. The five time parameters td0, td1, td2, td3, and td4 are set in advance.

[Step S2] Whether input data ends is decided. If the input data ends, then the process terminates.

[Step S3] Two pieces of input data are compared to decide whether they are in a same-logical-level state (whether their values are the same). If the two pieces of input data are in a same-logical-level state, then step S7 is performed.

[Step S4] If they are not in a same-logical-level state, then same-logical-level detection signal (EOP) output is changed to a differential state (L). After a delay of td0, differential output D is outputted in its original condition.

[Step S5] Whether the two pieces of input data have changed to polarities opposite to each other is decided. If the two pieces of input data have not changed to polarities opposite to each other, then the process returns to step S2 and the next data is processed.

[Step S6] If the two pieces of input data have changed to polarities opposite to each other, then one pulse of a same-logical-level detection signal EOP is outputted, the process returns to step S2, and the next data is processed.

[Step S7] If the two pieces of input data are in a same-logical-level state, then same-logical-level detection signal EOP output is changed to a same-logical-level state (H).

[Step S8] Differential output D at the time of the two pieces of input data being in a same-logical-level state is adjusted and a short pulse signal is generated on the differential output D. Then the process returns to step S2 and the next data is processed.

By performing the above-mentioned processing procedure, the processing function of the differential interface circuit model shown in FIG. 5 is realized by software.

As stated above, by applying the differential interface circuit model to a logical simulation, a general-purpose emulator, an FPGA board, and the like, a desired circuit function can be verified.

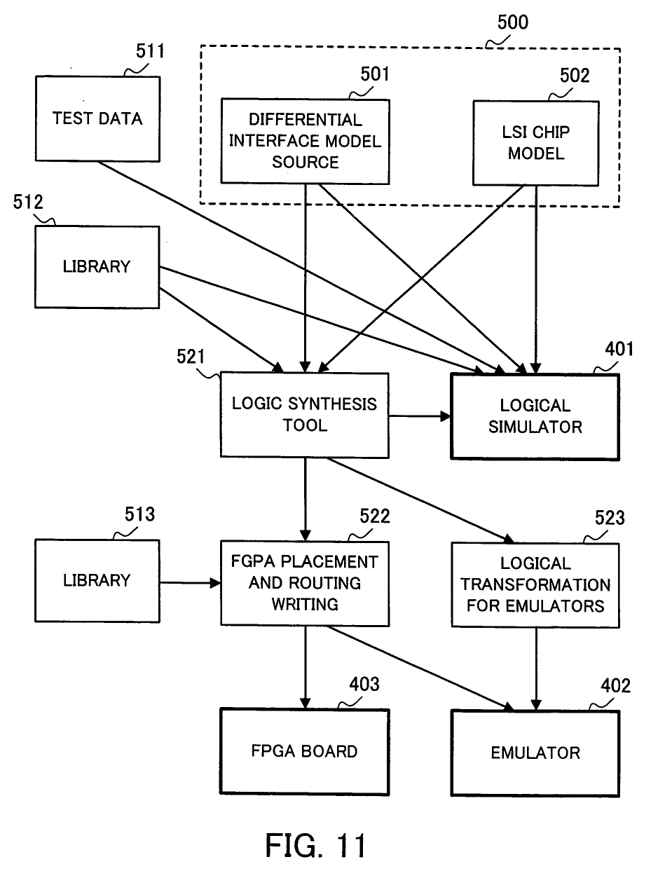

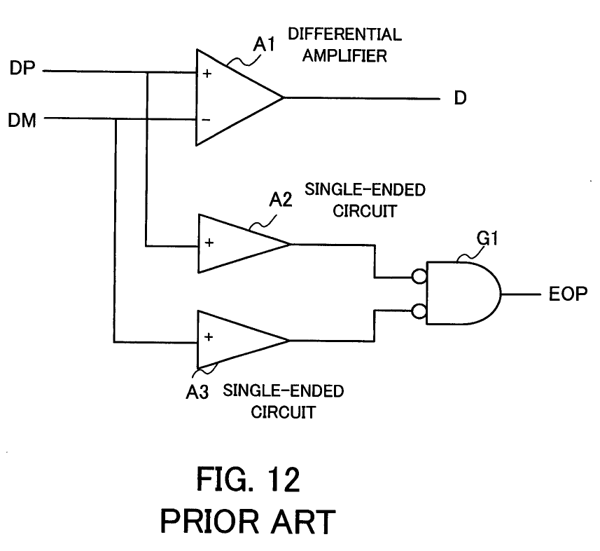

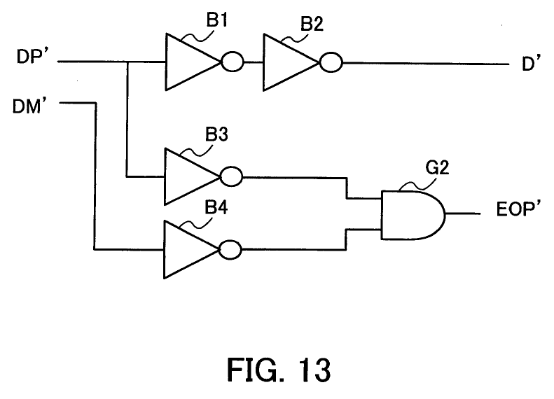

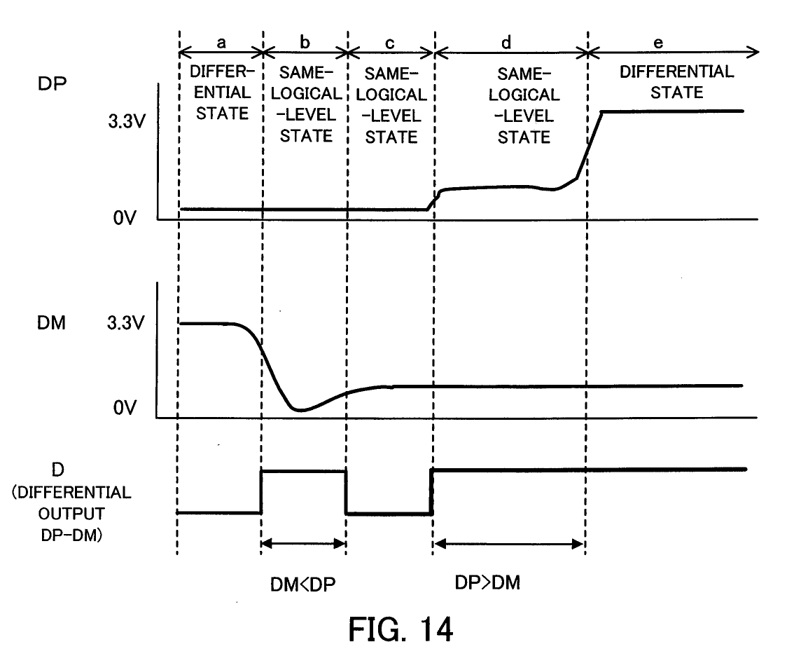

Relationships among a logical simulation, an emulator, and an FPGA board will now be described. FIG. 11 shows relationships among components in circuit function verification to which the differential interface circuit model according to the embodiment of the present invention is applied. Descriptions of the function and operation of the differential interface circuit model are registered in a source library 500 as a differential interface model source 501. Descriptions of the function and operation of an LSI chip are registered in the source library 500 as an LSI chip model 502. By synthesizing this source data, test data 511, and a library 512 including detailed descriptions of parts with a logic synthesis tool 521, a logical simulator 401 is generated. The logical simulator 401 generated is used for verifying the function of the LSI on a computer. Moreover, a general-purpose emulator on which data obtained by performing a logical transformation on data for logical simulators generated by the logic synthesis tool 521 with a logical transformation for emulators 523 is transported can be used as an emulator 402. In addition, by converting the data for logical simulators from the logic level to the gate level by FGPA placement and routing writing 522 by the use of a library for FPGAs 513, an FPGA board 403 can be fabricated. By using the FPGA board 403, the function of an LSI can be verified at a higher speed.

By registering the differential interface model in a library in this way, other designers can also use it. As a result, products can be developed in a short period of time, development costs can be reduced, and products to which they are applied can be placed quickly on the market.

In the circuit function verification method according to the present invention, by faithfully reproducing an analog transient response by the use of the differential interface circuit model in which when a change in the logic level of differential input is detected, an output value before the change in the logic level of the differential input is inverted for a predetermined period of time, the function of a circuit including a differential interface circuit is verified. By adopting the circuit function verification method using the differential interface circuit model, a logical simulation of the influence of a change in differential output caused by a minute change peculiar to analog signals can be done at the design stage.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A circuit function verification method for simulating the operation of a differential interface circuit which generates a differential circuit output signal according to the differential between differential input signals and for verifying the function of a circuit including the differential interface circuit, the method comprising the steps of:
inputting a first differential input signal and a second differential input signal, being a pair of differential signals, and detecting a change in the logical level of the first differential input signal and/or the second differential input signal by a signal change detection section; and
generating an inverted signal according to the detected change in the logical level of the first differential input signal and/or the second differential input signal by inverting a differential circuit output value before the change in the logical level of the first differential input signal and the second differential input signal for required time by a signal conversion section, and treating the inverted signal as a differential interface circuit output signal by the signal conversion section.

2. The circuit function verification method according to claim 1, wherein when that the logical level of the first differential input signal and the second differential input signal are the same is detected, the inverted signal is generated by inverting the differential interface circuit output value before the change of the first differential input signal and the second differential input signal to the same logical level while the first differential input signal and the second differential input signal are at the same logical level.

3. The circuit function verification method according to claim 2, wherein edges of the waveform of the inverted signal outputted while the first differential input signal and the second differential input signal are at the same logical level are delayed by a time parameter set in advance.

4. The circuit function verification method according to claim 3, wherein the inverted signal is outputted delay time set in advance by the time parameter after the time when that the first differential input signal and the second differential input signal changed to the same logical level is detected.

5. The circuit function verification method according to claim 3, wherein the inverted signal is maintained for time set in advance by the time parameter from the time when the outputting of the inverted signal is begun.

6. The circuit function verification method according to claim 3, wherein a next inverted signal is outputted delay time set in advance by the time parameter after the time when the outputting of the inverted signal terminates.

7. The circuit function verification method according to claim 3, wherein the time parameter is set to an arbitrary value when the inverted signal is generated.

8. The circuit function verification method according to claim 1, wherein when a change to a logical level by which a state in which the first differential input signal and the second differential input signal are at the same logical level begins or ends is detected, the inverted signal is varied for required time and is outputted as the differential interface circuit output signal via a delay section for delaying the differential interface circuit output signal by predetermined time in respect to the first differential input signal and the second differential input signal.

9. The circuit function verification method according to claim 8, wherein time for which edges of the waveform of the inverted signal exist is varied by a time parameter set in advance.

10. The circuit function verification method according to claim 8, wherein when that the first differential input signal and the second differential input signal have changed logical levels to opposite level each other is detected, the differential interface circuit output signal according to the first differential input signal and the second differential input signal which are at the logical levels opposite to each other is outputted before the differential interface circuit output signal which is outputted via the delay section and which indicates that the first differential input signal and the second differential input signal are at the same logical level outputs the end of a state in which the first differential input signal and the second differential input signal are at the same logical level.

11. The circuit function verification method according to claim 1, wherein when a predetermined change in the logical level of the first differential input signal and the second differential input signal is detected, a same-logical-level detection signal which indicates that the first differential input signal and the second differential input signal are at a same logical level is generated by a second signal conversion section with a required frequency.

12. The circuit function verification method according to claim 11, wherein the same-Logical-level detection signal is generated when that the first differential input signal and the second differential input signal changed simultaneously to logical levels opposite to each other is detected.

13. A circuit function verification apparatus for simulating the operation of a differential interface circuit which generates a differential circuit output signal according to the differential between differential input signals and for verifying the function of a circuit including the differential interface circuit, the apparatus comprising:
a signal change detection section for accepting a first differential input signal and a second differential input signal, being a pair of differential signals, and for detecting a change in the logical level of the first differential input signal and/or the second differential input signal; and
a signal conversion section for generating an inverted signal according to the detected change in the logical level of the first differential input signal and/or the second differential input signal by inverting a differential circuit output value before the change in the logical level of the first differential input signal and the second differential input signal for required time, and for treating the inverted signal as a differential interface circuit output signal.

14. The circuit function verification apparatus according to claim 13, wherein the signal change detection section and the signal conversion section are emulators.

15. The circuit function verification apparatus according to claim 13, wherein the signal change detection section and the signal conversion section are FPGAs.

16. A circuit simulation program for simulating the operation of a differential interface circuit which generates a differential circuit output signal according to the differential between differential input signals, the program making a computer perform the steps of:
inputting a first differential input signal and a second differential input signal, being a pair of differential signals, and detecting a change in the logical level of the first differential input signal and/or the second differential input signal; and
generating an inverted signal according to the detected change in the logical level of the first differential input signal and/or the second differential input signal by inverting a differential circuit output value before the change in the logical level of the first differential input signal and the second differential input signal for required time, and treating the inverted signal as a differential interface circuit output signal.
